(19) United States
(12) Patent Application Publication
(10) Pub. No.: US 2005/0000795 A1
(43) Pub. Date: Jan. 6, 2005

(54) Magnetic recording medium and method of manufacturing the same

(75) Inventors: Naoki Takizawa, Nagano (JP); Takahiro Shimizu, Nagano (JP); Hiroyuki Uwazumi, Nagano (JP); Tadaaki Oikawa, Nagano (JP); Miyabi Nakamura, Nagano (JP)

Correspondence Address: STAAS & HALSEY LLP, SUITE 700, 1201 NEW YORK AVENUE, N.W., WASHINGTON, DC, 20005, US

(73) Assignee: FUJI ELECTRIC CO., LTD., Kawasaki (JP)

(21) Appl. No.: 10/898,981

(22) Filed: Jul. 27, 2004

Related U.S. Application Data
(62) Division of application No. 10/231,490, filed on Aug. 30, 2002.

(30) Foreign Application Priority Data
Aug. 31, 2001 (JP) 2001-264515

(51) Int. Cl. C23C 14/00; C23C 14/32; B32B 5/16

(52) U.S. Cl. 204/192.1; 204/192.12

(57) ABSTRACT

A magnetic recording medium exhibits a high coercive force and suppresses noises caused therefrom at a low level. The magnetic recording medium includes a nonmagnetic substrate, a nonmagnetic undercoating layer on the substrate where the undercoating layer has a hexagonal close packing structure or a combination of the hexagonal close packing structure and a body center cubic structure. The magnetic recording medium includes a nonmagnetic intermediate layer on the undercoating layer, where the intermediate layer has a hexagonal close packing structure or a combination of the hexagonal close packing structure and a body center cubic structure, and a magnetic layer on the intermediate layer. The magnetic layer has a granular structure formed of ferromagnetic crystal grains and oxide grain boundaries or nitride grain boundaries surrounding the ferromagnetic crystal grains.

### CROSS-REFERENCE TO RELATED APPLICATIONS

This application is a divisional of application Ser. No. 10/231,490, filed Aug. 30, 2002, pending.

This application is based upon and claims the priority of Japanese Application No. 2001-264515 filed Aug. 31, 2001, and U.S. patent application Ser. No. 10/231,490, filed Aug. 30, 2002, the contents being incorporated herein by reference.

### BACKGROUND OF THE INVENTION

1. Field of the Invention

The present invention relates to a magnetic recording medium and a method of manufacturing the magnetic recording medium, and more particularly, the present invention relates to a magnetic recording medium used in a hard disk drive and a method of manufacturing the magnetic recording medium.

2. Description of the Related Art

Recently, it is required for the magnetic recording medium in a hard disk drive to exhibit a higher recording density. In order to meet demands for the higher recording density, it is important to improve a coercive force of a thin magnetic film and to suppress noises caused therefrom at a low level. Various compositions and structures for a magnetic layer and various materials for a nonmagnetic undercoating layer have been proposed to improve the coercive force and to reduce the noises.

A granular magnetic layer, including magnetic crystal grains and a nonmagnetic and nonmetallic material such as an oxide and a nitride surrounding the magnetic crystal grains, is known. Because grain boundaries formed of the nonmagnetic and nonmetallic material, physically separate the magnetic crystal grains, a magnetic interaction between the magnetic crystal grains is depressed and zigzag domain walls are prevented from occurring in transient regions between recording bits. Therefore, the granular magnetic layer is favorable to suppress the noises at the low level.

When a conventional CoCr metallic magnetic film is formed at a high temperature, Cr is segregated from Co magnetic crystal grains to the grain boundaries and the segregated Cr reduces magnetic interaction between the magnetic grains. Because the nonmagnetic and nonmetallic material used for the grain boundaries in the granular magnetic film is segregated more easily than Cr, the nonmagnetic and nonmetallic material in the granular magnetic film facilitates isolating the magnetic crystal grains from each other. For segregating a sufficient amount of Cr, it is indispensable to heat a substrate at 200° C. or higher during formation of the CoCr metallic magnetic film. In contrast, the nonmagnetic and nonmetallic material is segregated even when the granular magnetic film is not heated during a deposition thereof.

### SUMMARY OF THE INVENTION

Various objects and advantages of the invention will be set forth in part in the description that follows and, in part, will be obvious from the description, or may be learned by practice of the invention.

For obtaining desirable characteristics, especially for obtaining a high coercive force Hc, it is necessary to add a relatively large amount of Pt to a Co alloy to form a magnetic recording medium including a granular magnetic layer. In detail, in order to obtain a coercive force Hc of around 3200 Oe, it is necessary to add 16 at. % of expensive Pt. To provide the CoCr metallic magnetic film with the same coercive force Hc, it is enough to add around 12 at. % of Pt.

To realize a higher recording density, it is necessary to realize a high coercive force Hc of 3200 Oe or larger. Therefore, it is necessary to add a greater amount of expensive Pt, increasing manufacturing costs against demands for cost reduction. Because it has been required to reduce noises caused from a medium, it is also necessary to control properties of the granular magnetic film.

In view of the foregoing, it is a first object of the invention to provide a magnetic recording medium that facilitates obtaining a high coercive force and suppressing noises caused therefrom at a low level. It is a second object of the invention to provide a method of manufacturing the magnetic recording medium, in accordance with an embodiment of the present invention.

According to a first aspect of the invention, there is provided a magnetic recording medium is provided including: a nonmagnetic substrate; a nonmagnetic undercoating layer on the nonmagnetic substrate, the nonmagnetic undercoating layer having a hexagonal close packing structure or a combination of the hexagonal close packing structure and a body center cubic structure; a nonmagnetic intermediate layer on the nonmagnetic undercoating layer, the nonmagnetic intermediate layer having a hexagonal close packing structure or a combination of the hexagonal close packing structure and a body center cubic structure; and a magnetic layer on the nonmagnetic intermediate layer, the magnetic layer having a granular structure formed of ferromagnetic crystal grains and oxide grain boundaries or nitride grain boundaries surrounding the ferromagnetic crystal grains.

Advantageously, the oxide grain boundaries include an oxide including Mg, Al, Si, Ti, Cr, Mn, Co, Zr, Ta, W, or Hf. Advantageously, the nitride grain boundaries include a nitride including Mg, Al, Si, Ti, Cr, Mn, Co, Zr, Ta, W, or Hf. Advantageously, the hexagonal close packing structure of the nonmagnetic intermediate layer includes Ru, Ir, Rh, or Re. Advantageously, the combination of the hexagonal close packing structure and the body center cubic structure of the nonmagnetic intermediate layer includes an alloy including Ru, Ir, Rh, or Re, that contains from 10 at.% to 50 at.% of Ti, C, W, Mo, or Cu.

Advantageously, the hexagonal close packing structure of the nonmagnetic undercoating layer includes W, Mo, or V. Advantageously, the combination of the hexagonal close packing structure and the body center cubic structure of the nonmagnetic undercoating layer includes an alloy including W, Mo, Cr, or V, that contains from 10 at. % to 50 at. % of Ti. Advantageously, the nonmagnetic substrate is made of a crystallized glass, a chemically strengthened glass, or a resin.

According to a second aspect of the invention, there is provided a method of manufacturing a magnetic recording medium including a nonmagnetic substrate; a nonmagnetic undercoating layer on the nonmagnetic substrate, the nonmagnetic undercoating layer having a hexagonal close packing structure or a combination of a hexagonal close packing structure and a body center cubic structure; a nonmagnetic intermediate layer on the nonmagnetic undercoating layer, the nonmagnetic intermediate layer having a hexagonal close packing structure or a combination of the hexagonal close packing structure and a body center cubic structure; and a magnetic layer on the nonmagnetic intermediate layer, the magnetic layer having a granular structure formed of ferromagnetic crystal grains and oxide grain boundaries or nitride grain boundaries surrounding the ferromagnetic crystal grains. The method includes: setting a spacing between a target in a sputtering apparatus and the substrate to form the nonmagnetic intermediate layer and/or to form the magnetic layer at a spacing between 70 mm and 100 mm.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

The above objective and advantage of the present invention will become more apparent by describing in detail preferred embodiments thereof with reference to the attached drawings in which:

FIG. 1 is a cross sectional view of a magnetic recording medium according to an embodiment of the invention.

FIG. 2 is a curve relating a T/S spacing at a deposition of a nonmagnetic intermediate layer and a coercive force.

FIG. 3 is a curve relating the T/S spacing at the deposition of the nonmagnetic intermediate layer and a signal noise ratio SNR.

FIG. 4 is a curve relating the T/S spacing at the deposition of a magnetic layer and the coercive force.

FIG. 5 is a curve relating the T/S spacing at the deposition of the magnetic layer and the signal noise ratio SNR.

FIG. 6 is a curve relating the coercive force and the T/S spacing at a deposition of the nonmagnetic intermediate layer and the magnetic layer.

FIG. 7 is a curve relating the signal noise ratio SNR and the T/S spacing at the deposition of the nonmagnetic intermediate layer and the magnetic layer.

### DETAILED DESCRIPTION OF THE PREFERRED EMBODIMENTS

Hereinafter, embodiments of the present invention will be described in detail with reference to the attached drawings. The present invention may, however, be embodied in many different forms and should not be construed as being limited to the embodiments set forth herein; rather, these embodiments are provided so that the present disclosure will be thorough and complete, and will fully convey the concept of the invention to those skilled in the art.

A granular magnetic film according to an embodiment of the invention, facilitates obtaining a high coercive force and reducing noises and manufacturing costs. The granular magnetic film is manufactured by adjusting a spacing between a target and a substrate in a sputtering apparatus (hereinafter referred to as the “T/S spacing”). When the T/S spacing is set at 40 mm or longer to form a nonmagnetic intermediate layer or a magnetic layer, a growth rate of the nonmagnetic intermediate layer or the magnetic layer is low enough to obtain the nonmagnetic intermediate layer to grow uniformly or the magnetic layer to grow uniformly. Thus, an initial growth of the granular magnetic film is improved and an amount of Pt staying in ferromagnetic grains is increased, therefore, a high coercive force is obtained easily.

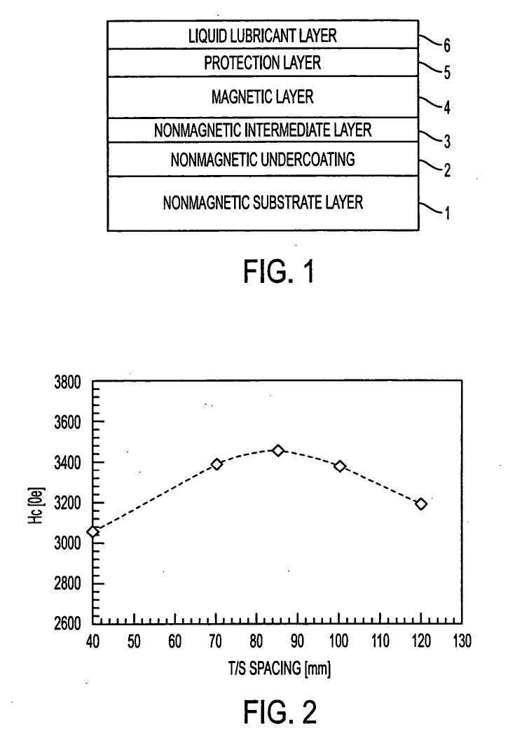

FIG. 1 is a cross sectional view of a magnetic recording medium according to an embodiment of the invention.

Referring now to FIG. 1, the magnetic recording medium according to an embodiment of the present invention includes a nonmagnetic substrate 1, a nonmagnetic undercoating layer 2 on the nonmagnetic substrate 1, a nonmagnetic intermediate layer 3 on the nonmagnetic undercoating layer 2, a magnetic layer 4 on the nonmagnetic intermediate layer 3, a protection layer 5 on the magnetic layer 4, and a liquid lubricant layer 6 on the protection layer 5.

An Al alloy substrate provided with NiP plating, a chemically strengthened glass substrate, a crystallized glass substrate, and a substrate used for a conventional magnetic recording media may be used for the nonmagnetic substrate 1. Because the substrate is not heated, according to an embodiment of the invention, substrates formed by injection molding a polycarbonate resin, a polyolefin resin or similar resins are also employable for the nonmagnetic substrate 1.

The nonmagnetic undercoating layer 2 may be made of W, Mo, or V. In the alternative, the nonmagnetic undercoating layer 2 may be made of a W alloy, an Mo alloy, a Cr alloy or a V alloy, each containing from 10 to 50 at. % of Ti. The nonmagnetic undercoating layer 2 may be 5 to 100 nm in thickness, although any limitation does not exist in the thickness of the nonmagnetic undercoating layer 2.

The nonmagnetic intermediate layer 3 may be made of Ru, Ir, Rh, or Re. In the alternative, the nonmagnetic intermediate layer 3 may be made of a Ru alloy, an Ir alloy, a Rh alloy or a Re alloy, each containing 10 to 50 at. % of Ti, C, W, Mo or Cu. The nonmagnetic intermediate layer 3 may be 2 to 50 nm in thickness, although any limitation does not exist in the thickness of the nonmagnetic intermediate layer 3.

The magnetic layer 4 is a granular magnetic layer formed of ferromagnetic crystal grains and nonmagnetic grain boundaries surrounding the ferromagnetic crystal grains. The nonmagnetic grain boundaries include a metal oxide or a metal nitride. The above described structure of the magnetic layer 4 is formed by a sputtering method using a ferromagnetic metal target containing an oxide to constitute the nonmagnetic grain boundaries or by the reactive sputtering method using the ferromagnetic metal target in an Ar sputtering gas containing oxygen.

CoPt alloys may be used for a material of the ferromagnetic crystal, although the material of the ferromagnetic crystal is not limited to the CoPt alloys. To reduce the noises caused from the recording media, Cr, Ni or Ta to the CoPt alloys may be added. To obtain a stable granular structure, an oxide including Mg, Al, Si, Ti, Cr, Mn, Co, Zr, Ta, W, or Hf may be employed for the material of the nonmagnetic grain boundaries. It is necessary for the magnetic layer 4 to be thick enough to obtain sufficiently high reproduced signals outputted from a magnetic head. A thin film containing carbon as a main component is used for the protection layer 5. Perfluoropolyether lubricants may be used for the liquid lubricant layer 6.

A method of manufacturing a magnetic recording medium according to an embodiment of the invention will be described below.

The T/S spacing is set to form the nonmagnetic intermediate layer 3 and the magnetic layer 4 at any spacing between 70 mm and 100 mm. The method of manufacturing the magnetic recording medium, according to an embodiment of the invention, facilitates obtaining the magnetic recording medium as shown in FIG. 1, that exhibits a high coercive force and suppresses the noises caused therefrom at a low level, even when heating the substrate included in the conventional manufacturing method is omitted. Therefore, the manufacturing method according to an embodiment of the present invention facilitates reducing manufacturing steps and manufacturing costs.

As described above, the magnetic recording medium exhibiting a high coercive force Hc is obtained and an addition amount of precious Pt is reduced by optimizing the T/S spacing forming the nonmagnetic intermediate later and the magnetic layer. The magnetic recording medium according to an embodiment of the invention facilitates suppressing the noises caused at a low level. Because it is not necessary to heat the substrate in advance to deposit the constituent layers, manufacturing steps and manufacturing costs are reduced. Because it is not necessary to heat the substrate, inexpensive plastic substrates are used without a problem.

### First Embodiment

A chemically strengthened glass substrate (N-10 supplied from Hoya Corp.) having a flat and a smooth surface is used for the nonmagnetic substrate 1. The nonmagnetic substrate 1 is cleaned elaborately and loaded in the sputtering apparatus. The wolfram (W) nonmagnetic undercoating layer 2 of 30 nm in thickness is formed under an Ar gas pressure of 15 mTorr and at the T/S spacing of 40 mm. Then, the ruthenium (Ru) nonmagnetic intermediate layer 3 of 30 nm in thickness is formed under the Ar gas pressure of 15 mTorr and at the T/S spacing between 40 mm and 120 mm. Then, the magnetic layer 4 of 15 nm in thickness is formed by an RF sputtering method using a CoCr10Pt14 target containing 7 mole % of SiO₂ under the Ar gas pressure of 30 mTorr and at the T/S spacing of 40 mm. Then, the carbon protection layer 5 of 10 nm in thickness is deposited. Finally, the liquid lubricant layer 6 of 1.5 nm in thickness is coated on the laminate formed so far and removed from the sputtering apparatus, resulting in a magnetic recording medium having the structure as shown in FIG. 1. The substrate is not heated in advance to depositing the constituent layers.

FIG. 2 is a curve relating the T/S spacing at a deposition of the nonmagnetic intermediate layer and the coercive force. The coercive force is measured with a vibrating sample magnetometer (hereinafter referred to as a “VSM”). As FIG. 2 indicates, an excellent coercive force Hc is obtained by setting the T/S spacing between 70 mm and 100 mm, and the maximum coercive force is obtained at the T/S spacing of around 85 mm. In the measurements, a product Br δ of a remnant magnetic flux density and a thickness of samples is fixed at 50 G μm.

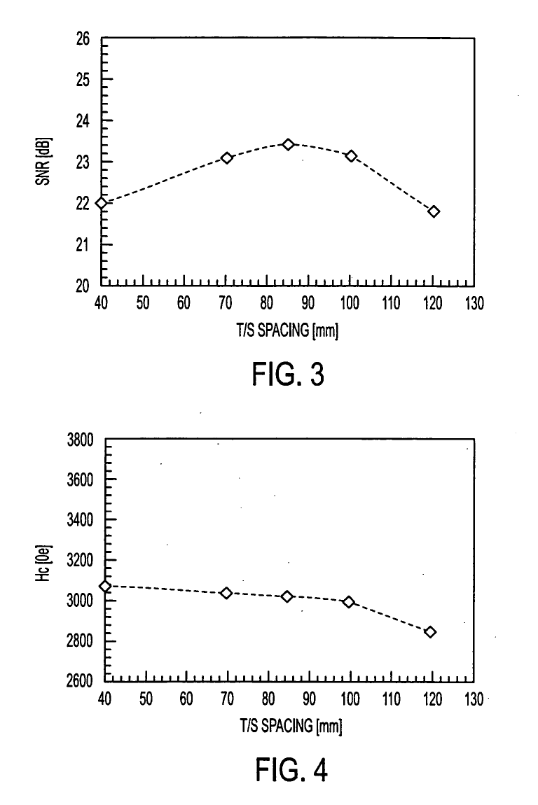

FIG. 3 is a curve relating the T/S spacing at the deposition of the nonmagnetic intermediate layer and a signal noise ratio SNR. The signal noise ratio SNR is measured in a spin stand tester using a giant magnetoresistance (GMR) head. Samples for the measurement are prepared such that equivalent signal outputs are reproduced from the samples. As FIG. 3 indicates, an excellent signal noise ratio SNR is obtained by setting the T/S spacing between 70 mm and 100 mm, and the maximum signal noise ratio SNR is obtained at the T/S spacing of around 85 mm.

### Second Embodiment

A chemically strengthened glass substrate (N-10 supplied from Hoya Corp.) having a flat and a smooth surface is used for the nonmagnetic substrate 1. The nonmagnetic substrate 1 is cleaned elaborately and loaded in the sputtering apparatus. The wolfram (W) nonmagnetic undercoating layer 2 of 30 nm in thickness is formed under the Ar gas pressure of 15 mTorr and at the T/S spacing of 40 mm. Then, the ruthenium (Ru) nonmagnetic intermediate layer 3 of 30 nm in thickness is formed under the Ar gas pressure of 15 mTorr and at the T/S spacing of 40 mm. Then, the magnetic layer 4 of 15 nm in thickness is formed by the RF sputtering method using a CoCr10Pt14 target containing 7 mole % of SiO₂ under the Ar gas pressure of 30 mTorr and at the T/S spacing between 40 mm and 120 mm. Then, the carbon protection layer 5 of 10 nm in thickness is deposited. Finally, the liquid lubricant layer 6 of 1.5 nm in thickness is coated on the laminate formed so far and removed from the sputtering apparatus, resulting in a magnetic recording medium having the structure as shown in FIG. 1. The substrate is not heated in advance to deposit the constituent layers.

FIG. 4 is a curve relating the T/S spacing at the deposition of the magnetic layer and the coercive force. The coercive force is measured with the VSM. As FIG. 4 indicates, the coercive force Hc lowers with increasing T/S spacing. The coercive force Hc lowers sharply as the T/S spacing exceeds 100 mm toward a wider side. In the measurements, the product Br δ of the remnant magnetic flux density and the thickness of the samples is fixed at 50 G μm.

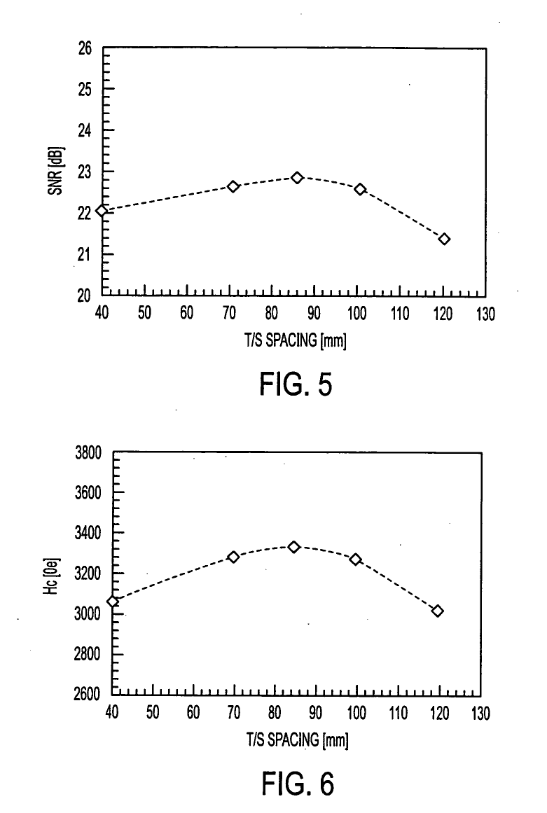

FIG. 5 is a curve relating the T/S spacing at the deposition of the magnetic layer and the signal noise ratio SNR. The signal noise ratio SNR is measured in a spin stand tester using the GMR head. The samples for the measurement are prepared such that equivalent signal outputs are reproduced from the samples. As FIG. 5 indicates, an excellent signal noise ratio SNR is obtained by setting the T/S spacing between 70 mm and 100 mm, and the maximum signal noise ratio SNR is obtained at the T/S spacing of around 85 mm.

### Third Embodiment

A chemically strengthened glass substrate (N-10 supplied from Hoya Corp.) having a flat and a smooth surface is used for the nonmagnetic substrate 1. The nonmagnetic substrate 1 is cleaned elaborately and loaded in the sputtering apparatus. The wolfram (W) nonmagnetic undercoating layer 2 of 30 nm in thickness is formed under the Ar gas pressure of 15 mTorr and at the T/S spacing of 40 mm. Then, the ruthenium (Ru) nonmagnetic intermediate layer 3 of 30 nm in thickness is formed under the Ar gas pressure of 15 mTorr and at the T/S spacing between 40 mm and 120 mm. Then, the magnetic layer 4 of 15 nm in thickness is formed by the RF sputtering method using a CoCr10Pt14 target containing 7 mole % of SiO₂ under the Ar gas pressure of 30 mTorr and at the T/S spacing between 40 mm and 120 mm. Then, the carbon protection layer 5 of 10 nm in thickness is deposited. Finally, the liquid lubricant layer 6 of 1.5 nm in thickness is coated on the laminate formed so far and removed from the sputtering apparatus, resulting in a magnetic recording medium having the structure as shown in FIG. 1. The substrate is not heated in advance to depositing the constituent layers.

FIG. 6 is a curve relating the coercive force and the T/S spacing at the deposition of the nonmagnetic intermediate layer and the magnetic layer. The coercive force is measured with the VSM. Although the coercive force Hc, according to the third embodiment, is lower than the coercive force Hc, according to the first embodiment shown in FIG. 2, the coercive force Hc according to the third embodiment is excellent at the T/S spacing between 70 mm and 100 mm. The maximum coercive force is obtained at the T/S spacing of around 85 mm. In the measurements, the product Br δ of the remnant magnetic flux density and the thickness of the samples is fixed at 50 G μm.

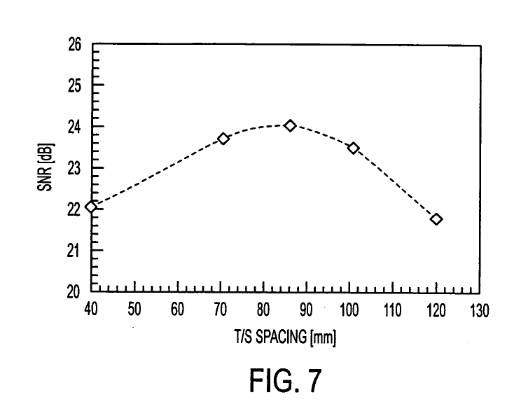

FIG. 7 is a curve relating the signal noise ratio SNR and the T/S spacing at the deposition of the nonmagnetic intermediate layer and the magnetic layer. The signal noise ratio SNR is measured in the spin stand tester using the GMR head. The samples for the measurement are prepared such that the equivalent signal outputs are reproduced from the samples. As FIG. 7 indicates, an excellent signal noise ratio SNR is obtained by setting the T/S spacing between 70 mm and 100 mm in the same manner as the signal noise ratios described in FIGS. 3 and 5 in connection with the first and second embodiments, respectively. The maximum signal noise ratio SNR is obtained at the T/S spacing of around 85 mm. The signal noise ratio SNR is best according to the third embodiment.

According to the first embodiment of the invention, the magnetic recording medium that exhibits a high coercive force Hc, is obtained. According to the third embodiment of the invention, the magnetic recording medium that exhibits the best signal noise ratio SNR, is obtained. Therefore, the magnetic recording medium that exhibits the desired characteristics is obtained by appropriately setting the T/S spacing to form the nonmagnetic intermediate layer or the T/S spacing to form the nonmagnetic intermediate layer and the nonmagnetic intermediate layer depending on the specifications of the magnetic recording medium.

The many features and advantages of the invention are apparent from the detailed specification and, thus, it is intended by the appended claims to cover all such features and advantages of the invention that fall within the true spirit and scope of the invention. Further, since numerous modifications and changes will readily occur to those skilled in the art, it is not desired to limit the invention to the exact construction and operation illustrated and described, and accordingly all suitable modifications and equivalents may be resorted to, falling within the scope of the invention.

1. A method of manufacturing a magnetic recording medium, the magnetic recording medium having a nonmagnetic substrate; a nonmagnetic undercoating layer on the nonmagnetic substrate, the nonmagnetic undercoating layer having a hexagonal close packing structure or a combination of the hexagonal close packing structure and a body center cubic structure; a nonmagnetic intermediate layer on the nonmagnetic undercoating layer, the nonmagnetic intermediate layer comprising a hexagonal close packing structure or a combination of the hexagonal close packing structure and a body center cubic structure; and a magnetic layer on the nonmagnetic intermediate layer, the magnetic layer having a granular structure formed of ferromagnetic crystal grains and oxide grain boundaries or nitride grain boundaries surrounding the ferromagnetic crystal grains, the method comprising:
forming the nonmagnetic intermediate layer by sputtering; and
forming the magnetic layer by sputtering, the forming of the nonmagnetic intermediate layer comprising setting a spacing between a target and the substrate at the spacing between 70 mm and 100 mm.

2. A method of manufacturing a magnetic recording medium, the magnetic recording medium having a nonmagnetic substrate; a nonmagnetic undercoating layer on the nonmagnetic substrate, the nonmagnetic undercoating layer having a hexagonal close packing structure or a combination of the hexagonal close packing structure and a body center cubic structure; a nonmagnetic intermediate layer on the nonmagnetic undercoating layer, the nonmagnetic intermediate layer comprising a hexagonal close packing structure or a combination of the hexagonal close packing structure and a body center cubic structure; and a magnetic layer on the nonmagnetic intermediate layer, the magnetic layer having a granular structure formed of ferromagnetic crystal grains and oxide grain boundaries or nitride grain boundaries surrounding the ferromagnetic crystal grains, the method comprising:
forming the nonmagnetic intermediate layer by sputtering; and
forming the magnetic layer by sputtering, the forming of the magnetic layer comprising setting a spacing between a target and the substrate at the spacing between 70 mm and 100 mm.

3. A method of manufacturing a magnetic recording medium, the magnetic recording medium having a nonmagnetic substrate; a nonmagnetic undercoating layer on the nonmagnetic substrate, the nonmagnetic undercoating layer having a hexagonal close packing structure or a combination of a hexagonal close packing structure and a body center cubic structure; a nonmagnetic intermediate layer on the nonmagnetic undercoating layer, the nonmagnetic intermediate layer comprising a hexagonal close packing structure or a combination of the hexagonal close packing structure and a body center cubic structure; and a magnetic layer on the nonmagnetic intermediate layer, the magnetic layer having a granular structure formed of ferromagnetic crystal grains and oxide grain boundaries or nitride grain boundaries surrounding the ferromagnetic crystal grains, the method comprising:
forming the nonmagnetic intermediate layer by sputtering; and
forming the magnetic layer by sputtering, the forming of the nonmagnetic intermediate layer and the forming of the magnetic layer comprising setting a spacing between a target and the substrate at the spacing between 70 mm and 100 mm.
